(19) United States
(12) Patent Application Publication
(10) Pub. No.: US 2025/0046668 A1
(43) Pub. Date: Feb. 6, 2025

(54) ENCAPSULATED WCSP WITH THERMAL PAD FOR EFFICIENT HEAT DISSIPATION

(71) Applicant: TEXAS INSTRUMENTS INCORPORATED, Dallas, TX (US)

(72) Inventors: Gail Edselle S. REYES, Angeles City (PH); Emerson M. ENIPIN, Angeles City (PH)

(21) Appl. No.: 18/362,556

(22) Filed: Jul. 31, 2023

(51) Int. Cl. H01L 23/367; H01L 23/00

(52) U.S. Cl. CPC H01L 23/3672; H01L 24/16; H01L 24/29; H01L 24/32; H01L 24/33; H01L 24/73; H01L 24/96; H01L 2224/16227; H01L 2224/29111; H01L 2224/29144; H01L 2224/2919; H01L 2224/29391; H01L 2224/32245; H01L 2224/3303; H01L 2224/33505; H01L 2224/33519; H01L 2224/73253; H01L 2224/96; H01L 2924/2064; H01L 2924/2065; H01L 2924/3512

(57) ABSTRACT

In some examples, a wafer chip scale package (WCSP) comprises a semiconductor die having a device side in which circuitry is formed and a non-device side opposite the device side, a solder bump electrically coupled to the circuitry, and a mold compound in contact with the device side, the solder bump, and four lateral sides of the semiconductor die. The package also comprises a thermal pad in contact with the non-device side of the semiconductor die and the mold compound.

### BACKGROUND

Semiconductor chips are often housed inside semiconductor packages that protect the chips from deleterious environmental influences, such as heat, moisture, and debris. A packaged chip communicates with electronic devices outside the package via conductive members, such as leads, that are exposed to surfaces of the package. Within the package, the chip may be electrically coupled to the conductive members using any suitable technique. One such technique is the flip-chip technique, in which the semiconductor chip (also called a “die”) is flipped so the device side of the chip (in which circuitry is formed) is facing downward. The device side is coupled to the conductive members using, e.g., solder bumps. Another technique is the wirebonding technique, in which the device side of the semiconductor chip is oriented upward and is coupled to the conductive members using bond wires.

### SUMMARY

In some examples, a wafer chip scale package (WCSP) comprises a semiconductor die having a device side in which circuitry is formed and a non-device side opposite the device side, a solder bump electrically coupled to the circuitry, and a mold compound in contact with the device side, the solder bump, and four lateral sides of the semiconductor die. The package also comprises a thermal pad in contact with the non-device side of the semiconductor die and the mold compound.

In some examples, a method for manufacturing a semiconductor device comprises positioning solder bumps on a device side of a semiconductor wafer, the device side having circuitry formed therein. The method also comprises cutting through a thickness of the semiconductor wafer to produce partial first and second trenches, and applying a mold compound to the device side, the solder bumps, and the partial first and second trenches. The method also comprises backgrinding the semiconductor wafer to reduce a thickness of the semiconductor wafer, the backgrinding producing first and second semiconductor dies. The method comprises coupling a thermal pad to a first non-device side of the first semiconductor die and a second non-device side of the second semiconductor die, separating the first and second semiconductor dies to produce a wafer chip scale package (WCSP), coupling a thermal interface material to the thermal pad of the WCSP, and coupling a heat sink to the thermal interface material.

### BRIEF DESCRIPTION OF THE DRAWINGS

FIG. 1 is a block diagram of an electronic device containing an encapsulated wafer chip scale package (EWCSP), in accordance with various examples.

FIG. 2A is a profile view of an EWCSP including a thermal pad, a thermal interface material (TIM), and a heat sink, in accordance with various examples.

FIG. 2B is a top-down view of an EWCSP including a thermal pad, a thermal interface material (TIM), and a heat sink, in accordance with various examples.

FIG. 2C is a perspective view of an EWCSP including a thermal pad, a thermal interface material (TIM), and a heat sink, in accordance with various examples.

FIG. 3A is a profile view of an EWCSP including a thermal interface material (TIM) and a heat sink, in accordance with various examples.

FIG. 3B is a top-down view of an EWCSP including a thermal interface material (TIM) and a heat sink, in accordance with various examples.

FIG. 3C is a perspective view of an EWCSP including a thermal interface material (TIM) and a heat sink, in accordance with various examples.

FIGS. 4A1-4I are a process flow for manufacturing an EWCSP including a thermal pad, a thermal interface material (TIM) and a heat sink, in accordance with various examples.

FIG. 5 is a flow diagram of a process for manufacturing an EWCSP including a thermal pad, a thermal interface material (TIM) and a heat sink, in accordance with various examples.

FIGS. 6A1-6H are a process flow for manufacturing an EWCSP including a thermal interface material (TIM) and a heat sink, in accordance with various examples.

FIG. 7 is a flow diagram of a process for manufacturing an EWCSP including a thermal interface material (TIM) and a heat sink, in accordance with various examples.

FIG. 8 is a graph depicting the relative mechanical stability provided by an EWCSP including a thermal pad, a thermal interface material (TIM) and a heat sink, in accordance with various examples.

FIG. 9 is a graph depicting the relative die stresses experienced under different ambient conditions by an EWCSP including a thermal pad, a thermal interface material (TIM) and a heat sink, in accordance with various examples.

FIG. 10 is a graph depicting the relative solder bump bridging risk of an EWCSP including a thermal pad, a thermal interface material (TIM) and a heat sink, in accordance with various examples.

FIG. 11 is a graph depicting the relative solder bump bridging risk of an EWCSP including a thermal pad, a thermal interface material (TIM) and a heat sink, in accordance with various examples.

### DETAILED DESCRIPTION

During the chip manufacturing process, circuitry is formed on a semiconductor (e.g., silicon) wafer in a fabrication facility. The wafer is later singulated (or “diced”) to produce individual dies, with each die having its own circuitry. In some cases, the dies are subsequently packaged, for example using lead frames, wire bonds, and mold compounds. However, in other cases, such as in wafer-level packaging, such packaging elements are applied to the wafer prior to wafer singulation.

Chip-scale packages (CSPs) are packages that have a relatively small package area-to-die area ratio. By some non-limiting definitions, a CSP has an area no greater than 1.2 times that of the die, and the package must be a single-die, direct surface mountable package. Wafer-level chip scale packages (WCSPs) are CSPs whose packaging components are applied to the wafer prior to wafer singulation. WCSPs are advantageous because they enable increased design flexibility, reduced manufacturing costs, and reduced overall size relative to traditional leaded packages, such as dual inline packages (e.g., with gullwing style leads). For at least these reasons, such packages are favored and frequently used in various industries, including the automotive industry.

Some WCSPs are encapsulated using a mold compound, and these WCSPs are known as encapsulated WCSPs. In encapsulated WCSPs, circuitry is formed in a device side of the die, and the circuitry is coupled to solder bumps or balls through a network of metal members, which may be called a redistribution layer (RDL). All sides of the die, as well as the RDL, are encapsulated by the mold compound. The encapsulated WCSP may then be mounted to a surface, such as a printed circuit board (PCB), by connecting the solder bumps to the electrical contacts on the PCB.

During operation, the die within an encapsulated WCSP (hereinafter, an EWCSP) generates heat. The heat follows the path of least resistance, which, in the case of an EWCSP, is through the RDL, the solder bumps, and to the PCB to which the EWCSP is coupled. Heat accumulation on the PCB, as well as in the EWCSP, due to heat dissipation inefficiencies can cause electrical performance and reliability problems.

This disclosure describes various examples of an EWCSP that mitigates the heat accumulation challenges described above. Specifically, the die within the EWCSP is encapsulated by a mold compound on five sides, but the top surface (i.e., the non-device side opposite the device side) of the die is not covered by the mold compound. Instead, the top surface of the die is covered by a thermal pad, such as a metal layer, that facilitates heat dissipation in a direction away from the PCB. This mitigates heat accumulation near the PCB and within the EWCSP. In some examples, a heat sink is indirectly coupled to the thermal pad by way of a thermal interface material (TIM) that facilitates heat transfer from the thermal pad to the heat sink. The heat sink may have physical properties that facilitate efficient heat dissipation, such as a multi-fin structure to increase the surface area exposed to the ambient environment. Together, the thermal pad, the TIM, and the heat sink increase the heat dissipation efficiency, directing heat away from the PCB and the EWCSP, thus mitigating the challenges associated with heat accumulation.

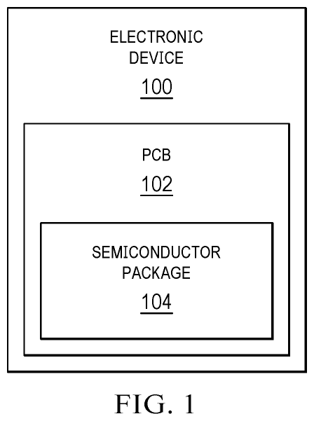

FIG. 1 is a block diagram of an electronic device 100 containing an encapsulated WCSP (EWCSP), in accordance with various examples. The electronic device 100 may be a laptop computer, a desktop computer, a notebook computer, a smartphone, a household or commercial appliance, a vehicle (e.g., an automobile, an aircraft, a spacecraft), an entertainment device (e.g., video gaming system, an audio device), or any other suitable type of device. The electronic device 100 may include a printed circuit board (PCB) 102, and a semiconductor package 104 may be coupled to the PCB 102. The semiconductor package 104 is an EWCSP, examples of which are described below with reference to the drawings.

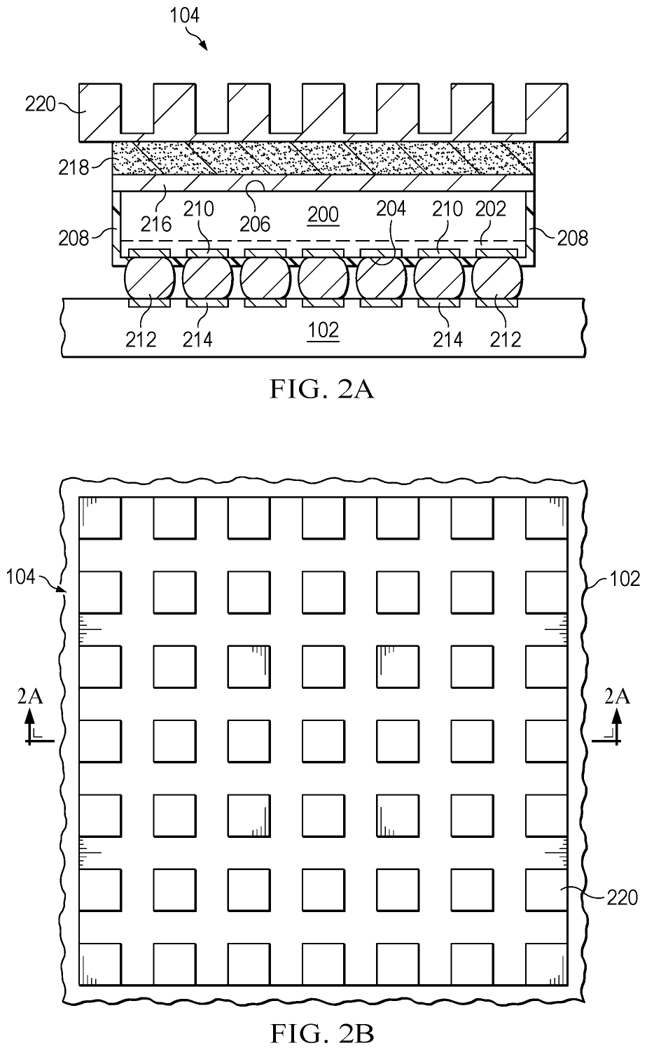

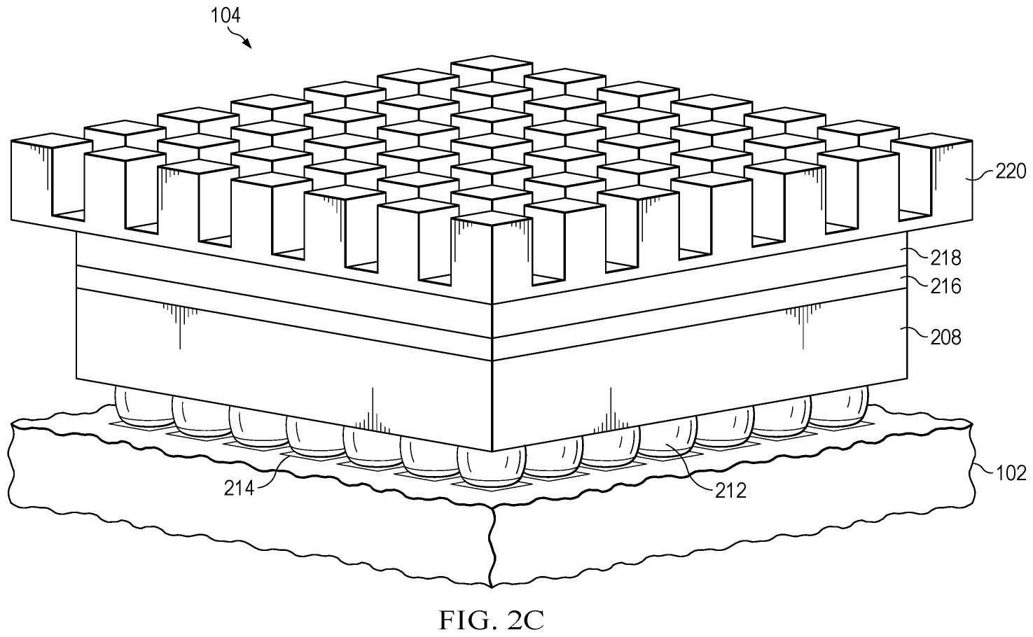

FIG. 2A is a profile view of an EWCSP including a thermal pad, a thermal interface material (TIM), and a heat sink, in accordance with various examples. Specifically, the package 104 is an EWCSP coupled to the PCB 102. The package 104 includes a semiconductor die 200. The semiconductor die 200 has a device side 204 and a non-device side 206 opposing the device side 204. The device side 204 has circuitry formed therein, and the type and/or operation of the circuitry may vary depending on the context in which the package 104 is implemented. The device side 204 also includes a network of metal members that interface between the aforementioned circuitry and contact pads 210, and this network of metal members may be referred to as a redistribution layer (RDL) 202. A mold compound 208 covers and contacts four lateral surfaces of the semiconductor die 200 and the device side 204 of the semiconductor die 200. Solder bumps 212 couple to the contact pads 210 and extend through the portion of the mold compound 208 contacting the device side 204 as shown.

The mold compound 208 does not cover or contact the non-device side 206 of the semiconductor die 200. Instead, the semiconductor package 104 includes a thermal pad 216, such as a metal layer (e.g., gold or tin), that covers and contacts the non-device side 206 and portions of the mold compound 208 as shown. The thermal pad 216 is applied to the non-device side 206 and portions of the mold compound 208 by any suitable technique, such as physical vapor deposition, chemical vapor deposition, and electroless plating. The thermal pad 216 is a strong conductor of heat, with a thermal conductivity coefficient of at least 24.5 watts per meter-Kelvin, with a thermal conductivity below this range being disadvantageous because the above-described challenges of inadequate heat dissipation will remain without an adequate thermal conduction path. The thickness of the thermal pad 216 ranges up to 4 microns, with a thickness above this range being disadvantageous because of the formation of metal burr defects encountered during the assembly process.

The semiconductor package 104 also includes a thermal interface material (TIM) 218 in contact with and coupled to the thermal pad 216. The TIM 218 may include HI-FLOW 300P produced by BERGQUIST®. The TIM 218 comprises a phase change compound and a thermally conductive polyimide film. In examples, the TIM 218 comprises a gap filler pad, such as a silicone compound pad. In examples, the TIM 218 comprises an acrylic adhesive. The TIM 218 has adhesive properties to couple to both a heat sink 220 and the thermal pad 216, and the adhesiveness ranges between 48 MPa and 100 MPa, with an adhesiveness below this range being disadvantageous because of the unacceptably high risk of delamination, and with an adhesiveness above this range being disadvantageous because unacceptable increases in manufacturing costs. The TIM 218 is a strong conductor of heat, with a thermal conductivity of at least 1.5 watts per meter-Kelvin in packages 104 including the thermal pad 216, with a thermal conductivity below this range being disadvantageous because the above-described challenges of inadequate heat dissipation will remain. The thickness of the TIM 218 ranges from 0.09 mm to 1.1 mm in packages 104 including the thermal pad 216, with a thickness below this range being disadvantageous because it provides an unacceptably inefficient path for heat conduction, and with a thickness above this range being disadvantageous because it occupies an unacceptably large amount of space. The thickness of the TIM 218 is between 0.1 millimeters and 0.5 millimeters in packages 104 excluding the thermal pad 216, with a thickness below this range being disadvantageous because it provides an unacceptably inefficient pathway for heat transfer, and with a thickness above this range being disadvantageous because it occupies an unacceptable amount of space.

The package 104 includes the heat sink 220. To maximize heat dissipation efficiency through the heat sink 220, the bottom surface of the heat sink has a horizontal area that ranges from 90 mm² to 160,000 mm², with an area smaller than this range being disadvantageous because of inefficient heat dissipation, and with an area larger than this range being disadvantageous because of unacceptable increases in space occupied and cost. The package 104 has a junction-to-ambient thermal resistance value (i.e., the thermal parameter that specifies how difficult it is for heat to flow from one location to another) ranging up to 50 degrees Celsius per watt, with a value above this range being disadvantageous because there is an inadequate heat path for heat dissipation.

FIG. 2B is a top-down view of the package 104 of FIG. 2A, in accordance with various examples. FIG. 2C is a perspective view of the package 104 of FIG. 2A, in accordance with various examples.

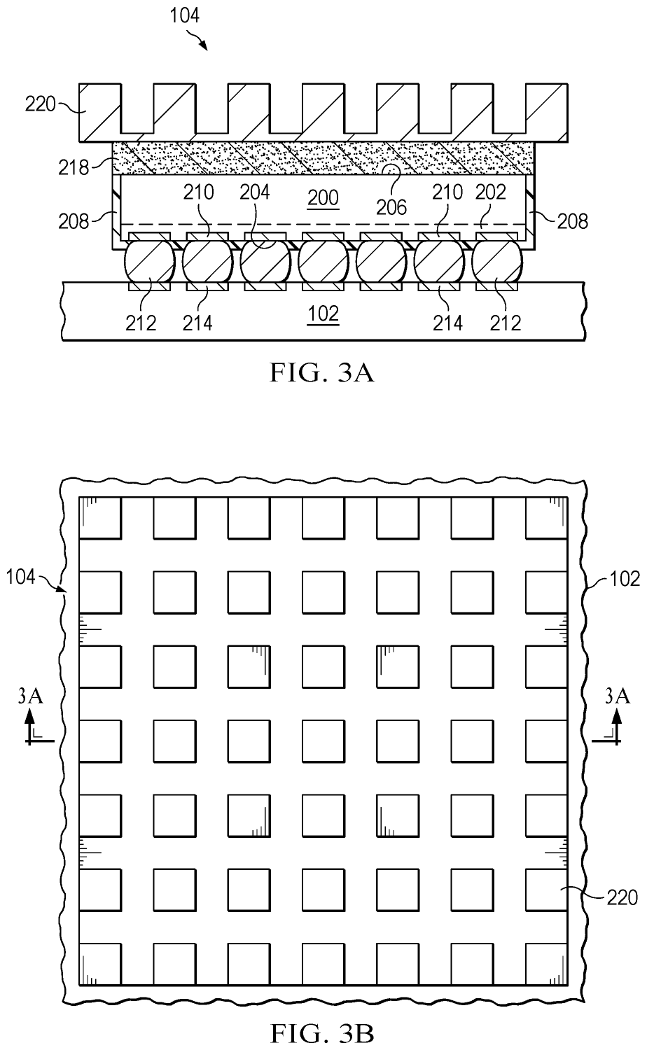

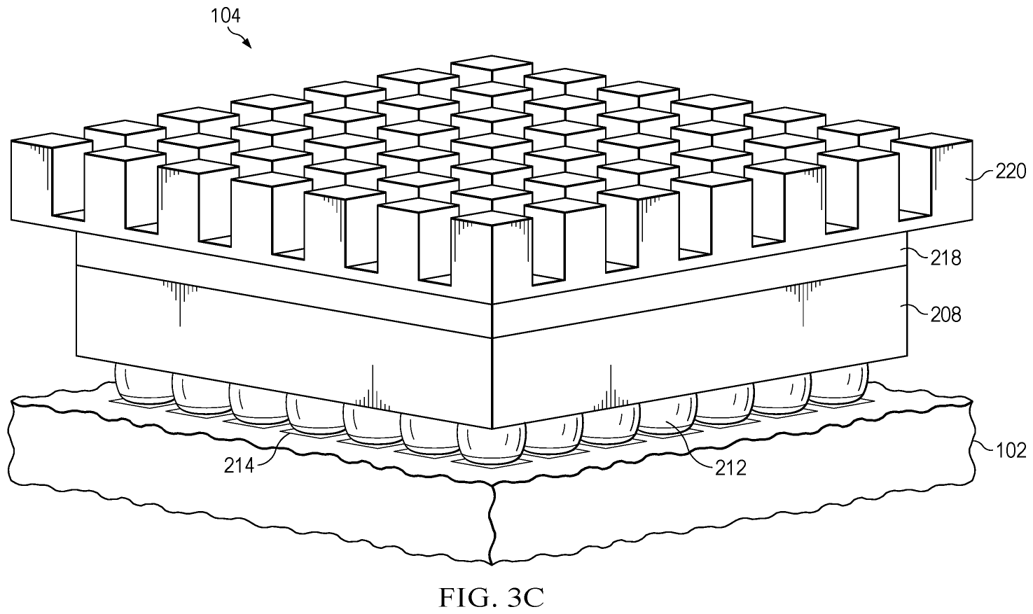

FIG. 3A is a profile view of an EWCSP including a thermal interface material (TIM) and a heat sink, in accordance with various examples. Specifically, FIG. 3A shows another example of the package 104. The package 104 of FIG. 3A is structurally identical to the example package 104 of FIG. 2A, except that the package 104 of FIG. 3A does not include the thermal pad 216. Instead, the TIM 218 is coupled to and contacts the non-device side 206 of the semiconductor die 200 and portions of the mold compound 208, as shown. FIG. 3B is a top-down view of the package 104 of FIG. 3A, in accordance with various examples. FIG. 3C is a perspective view of the package 104 of FIG. 3A, in accordance with various examples.

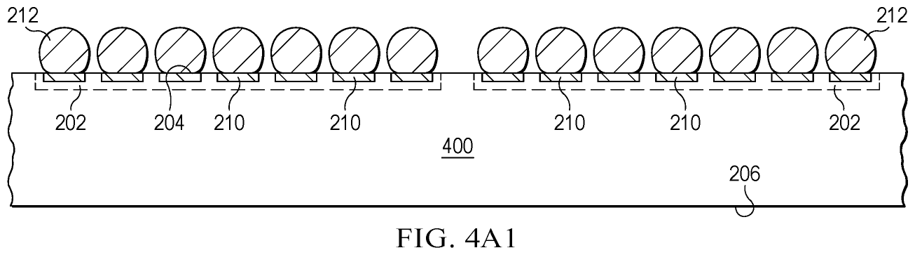

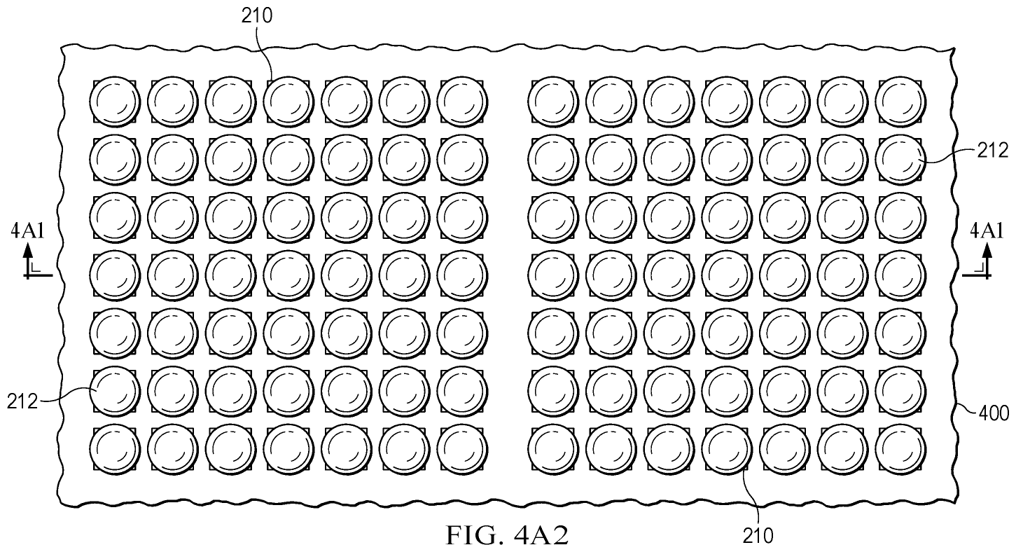

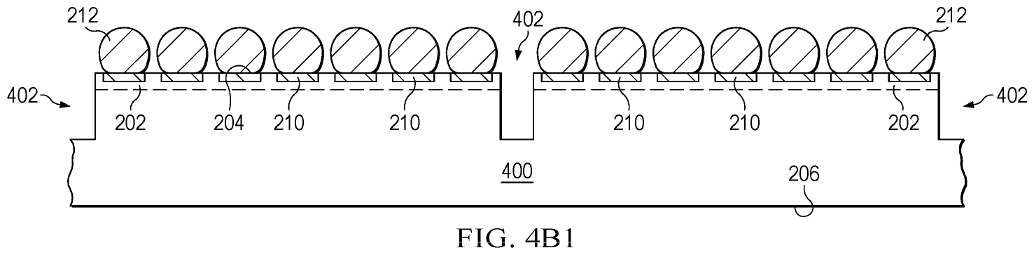

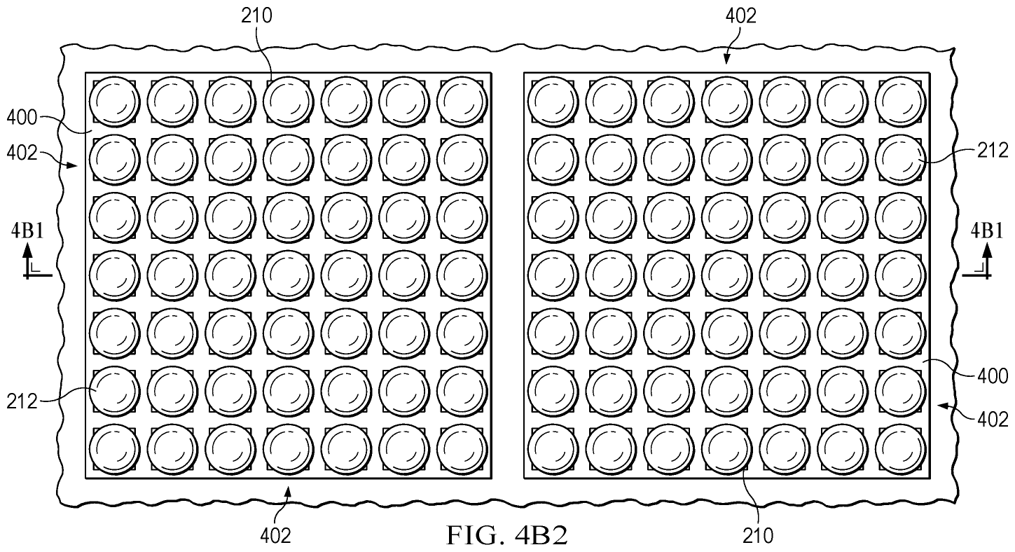

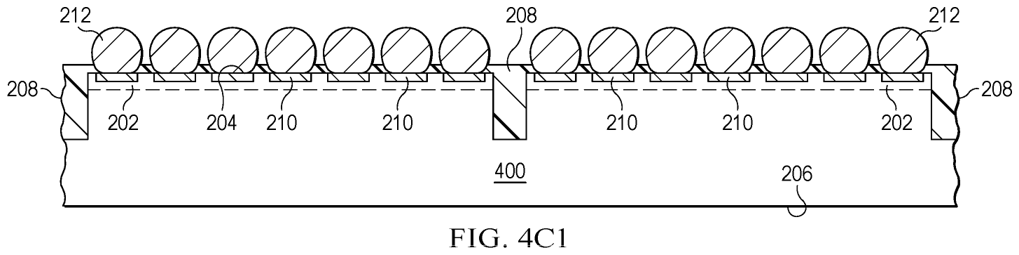

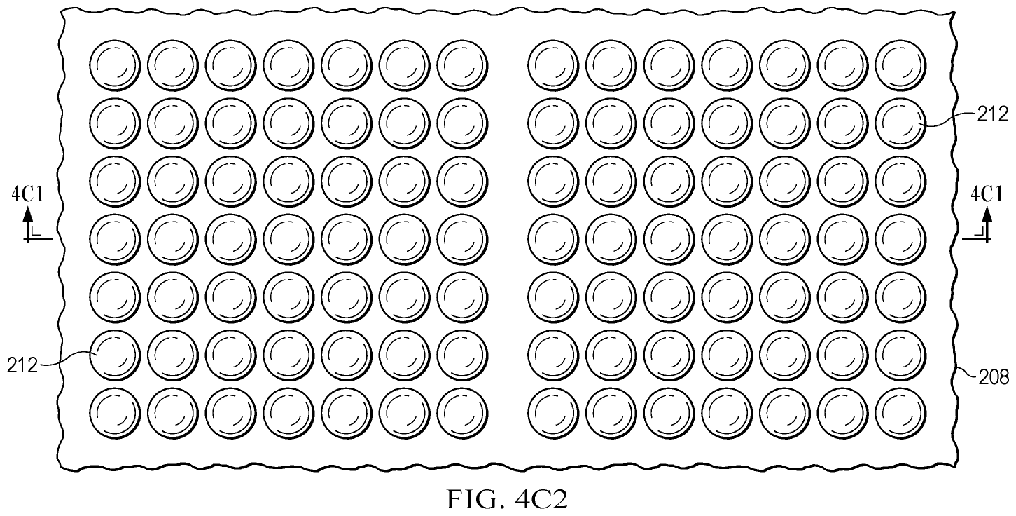

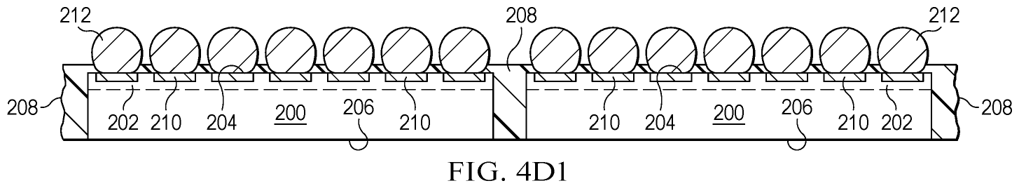

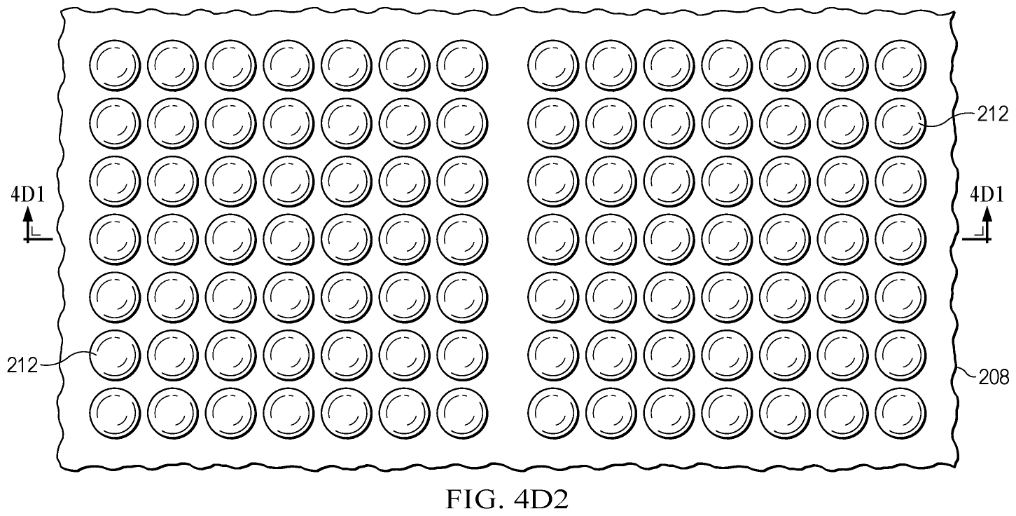

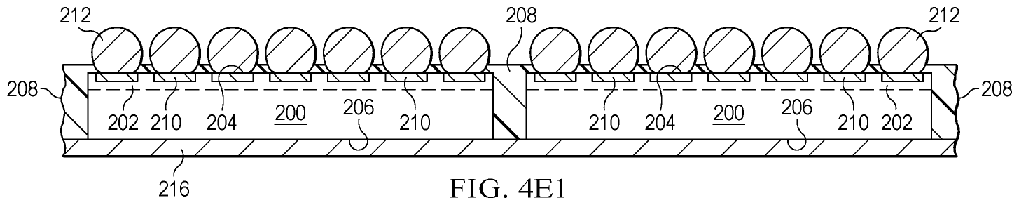

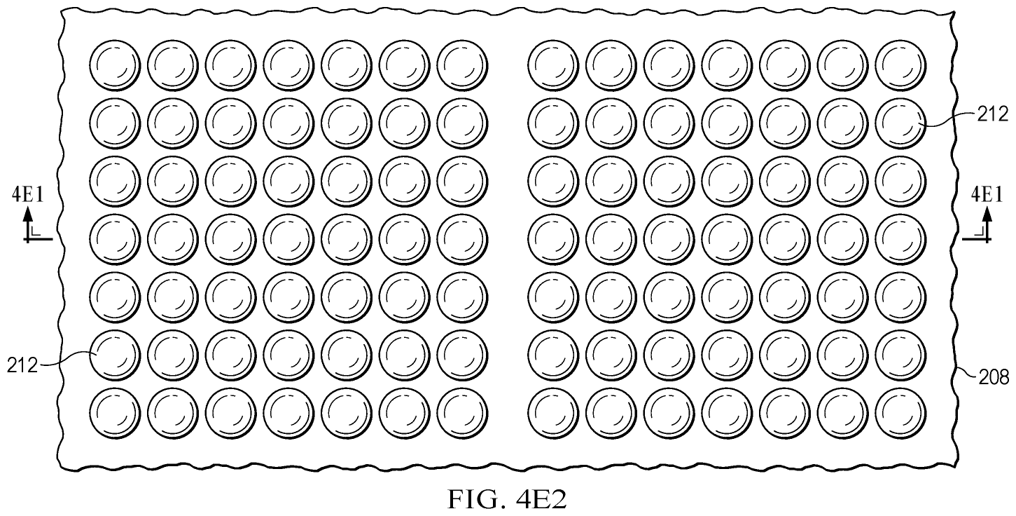

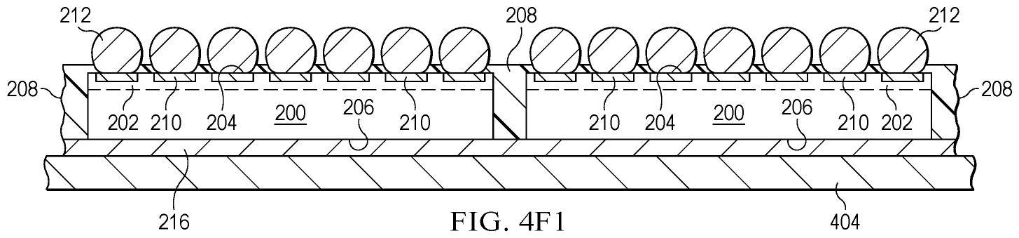

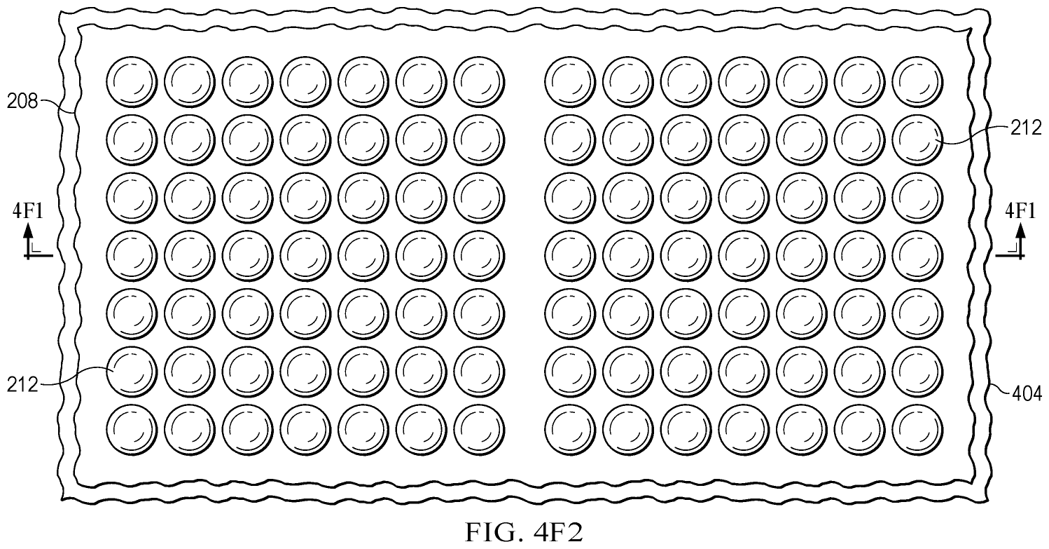

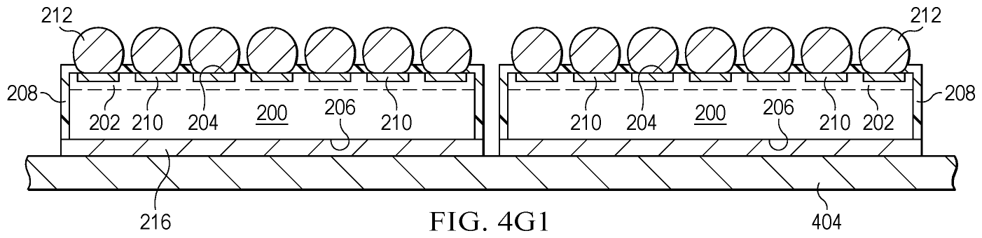

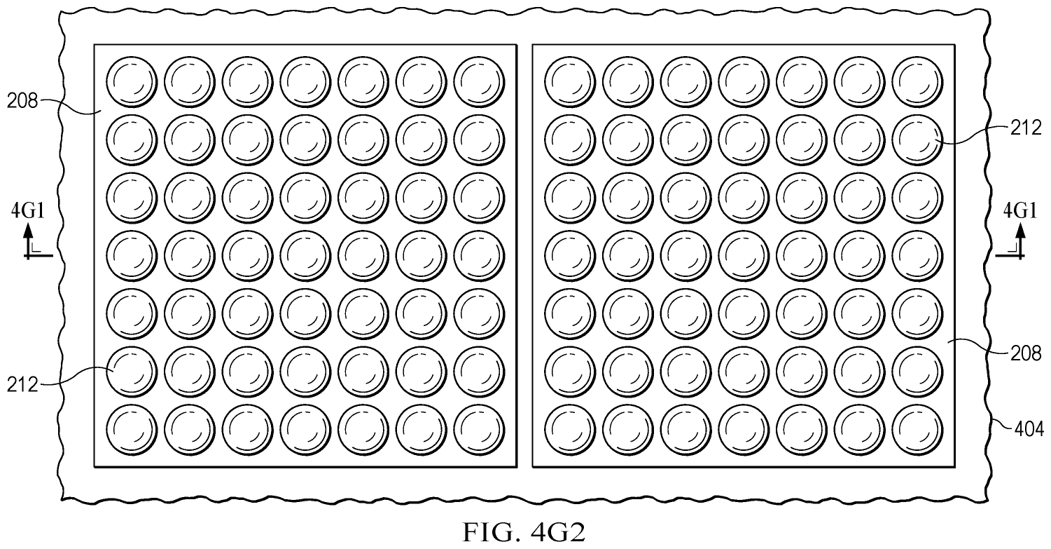

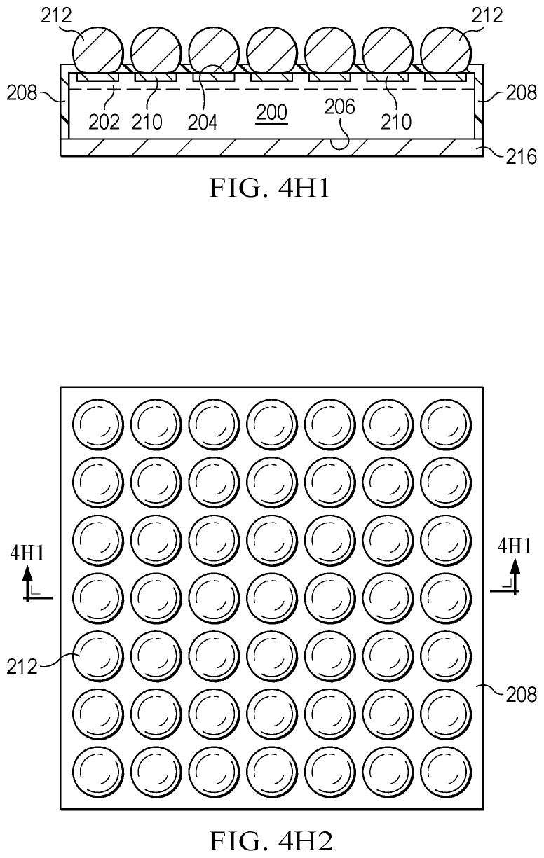

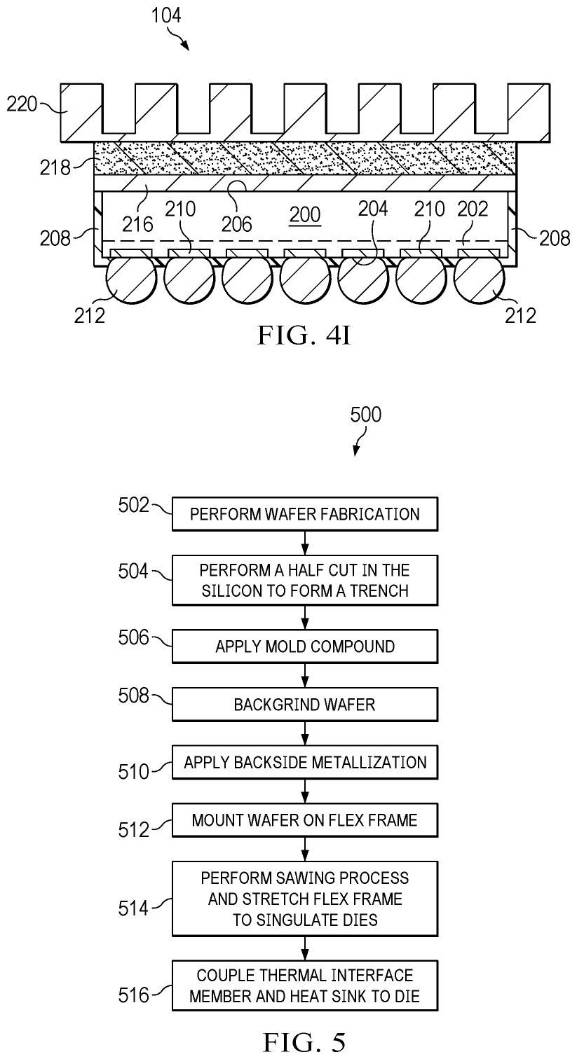

FIGS. 4A1-4I are a process flow for manufacturing an EWCSP including a thermal pad, a thermal interface material (TIM) and a heat sink, in accordance with various examples. For example, the process flow of FIGS. 4A1-4I depicts the manufacture of the example package 104 of FIG. 2A. FIG. 5 is a flow diagram of a method 500 for manufacturing the package 104, in accordance with various examples. Accordingly, FIGS. 4A1-4I and FIG. 5 are now described in parallel.

The method 500 begins with performing semiconductor wafer fabrication (502). In addition to fabricating circuitry and RDL 202 in a wafer 400, additional components, such as solder bumps 212, may be coupled to the device side 204 (e.g., to contact pads 210) of the wafer 400. FIG. 4A1 shows a cross-sectional view of the solder bumps 212 being coupled to the device side 204 of the wafer 400. FIG. 4A2 is a top-down view of the structure of FIG. 4A1, in accordance with various examples.

The method 500 includes performing half-cuts in the wafer 400 to form trenches (504). A “half-cut” is a cut in the wafer 400, formed by any suitable tool such as a mechanical saw or laser, that extends from the device side 204 to approximately halfway through the thickness of the wafer 400. The half-cut does not necessarily extend precisely to the midpoint of the thickness of the wafer 400. FIG. 4B1 shows a cross-sectional view of the structure of FIG. 4A1 having trenches 402 formed therein, and more specifically, in the device side 204. The trenches 402 may be formed in the scribe streets of the wafer 400, where the wafer 400 may later be singulated. FIG. 4B2 is a top-down view of the structure of FIG. 4B1, in accordance with various examples.

The method 500 includes applying a mold compound to the wafer (506). FIG. 4C1 shows the mold compound 208 applied to the wafer 400, and more specifically, to the device side 204 of the wafer 400. The mold compound 208 also fills the trenches 402, as shown. The mold compound 208 further surrounds and contacts the solder bumps 212, as shown, such that the solder bumps 212 extend from the contact pads 210, through the mold compound 208, and to an exterior of the mold compound 208. FIG. 4C2 is a top-down view of the structure of FIG. 4C1, in accordance with various examples.

The method 500 includes backgrinding the wafer (508). FIG. 4D1 shows the wafer 400 being backgrinded such that the portions of the wafer 400 through which the trenches 402 did not extend are removed from the wafer 400. Stated another way, the wafer 400 is backgrinded until individual dies 200 are formed, as shown. FIG. 4D2 is a top-down view of the structure of FIG. 4D1, in accordance with various examples.

The method 500 includes applying a backside metallization to the wafer (510). The backside metallization may form a thermal pad, such as the thermal pad 216 described above. FIG. 4E1 shows the thermal pad 216 applied to the non-device sides 206 of the dies 200, as well as to some portions of the mold compound 208, as shown. The thermal pad 216 may be applied by any suitable technique, such as physical vapor deposition, chemical vapor deposition, and electroless plating. FIG. 4E2 is a top-down view of the structure of FIG. 4E1, in accordance with various examples.

The method 500 includes mounting the structure of FIG. 4E1 on a flex frame (512). FIG. 4F1 shows the thermal pad 216 coupled to a flex frame 404. FIG. 4F2 is a top-down view of the structure of FIG. 4F1, in accordance with various examples.

The method 500 includes performing a sawing process and stretching the flex frame to singulate the dies (514). FIG. 4G1 shows a sawing process having been performed in the trenches 402, which includes sawing in the mold compound 208 and the thermal pad 216. FIG. 4G2 is a top-down view of the structure of FIG. 4G1, in accordance with various examples. FIG. 4H1 shows the resulting structure post-singulation and post-removal of the flex frame 404. FIG. 4H2 is a top-down view of the structure of FIG. 4H1, in accordance with various examples.

The method 500 includes coupling a thermal interface member and a heat sink to the die (516). FIG. 4I shows the TIM 218 coupled to the thermal pad 216, and the heat sink 220 coupled to the TIM 218, as described above and in accordance with various examples.

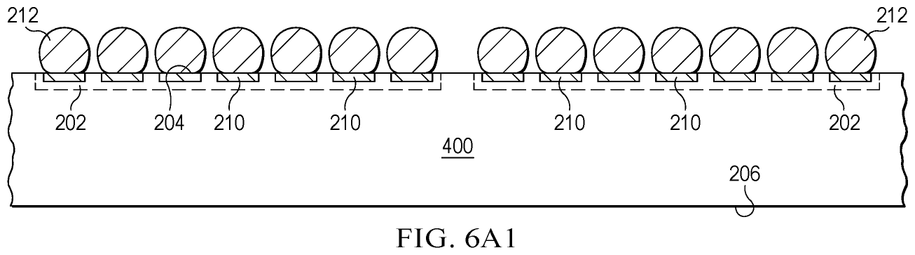

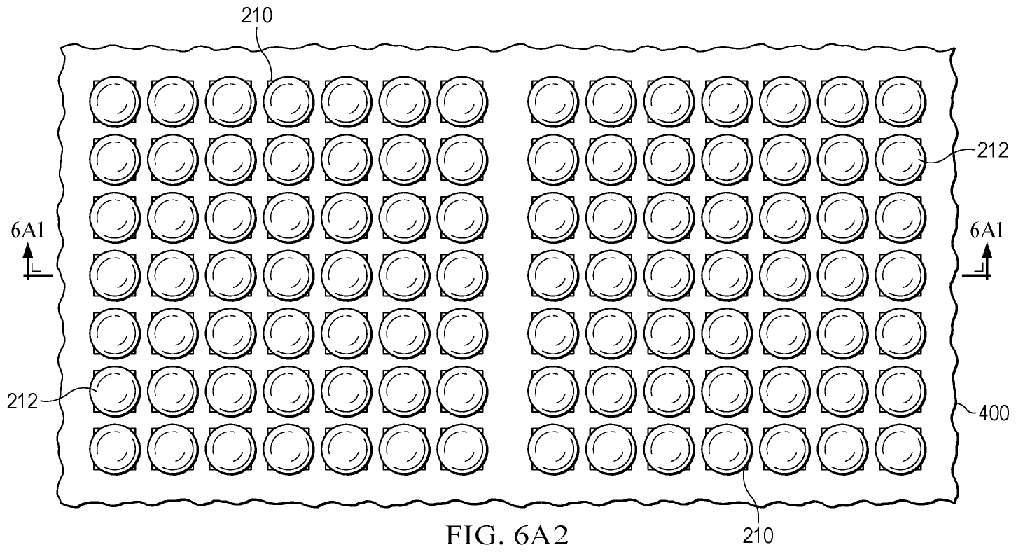

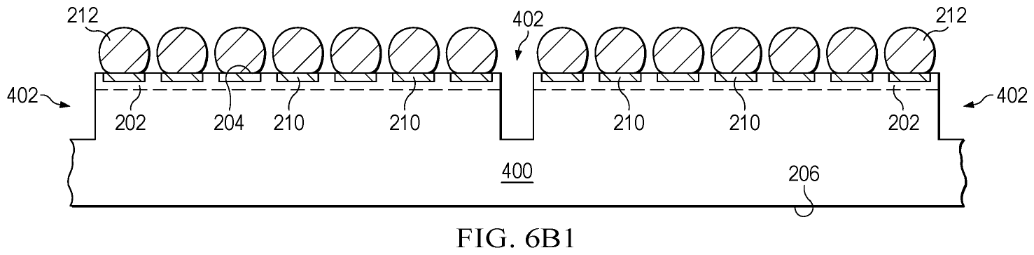

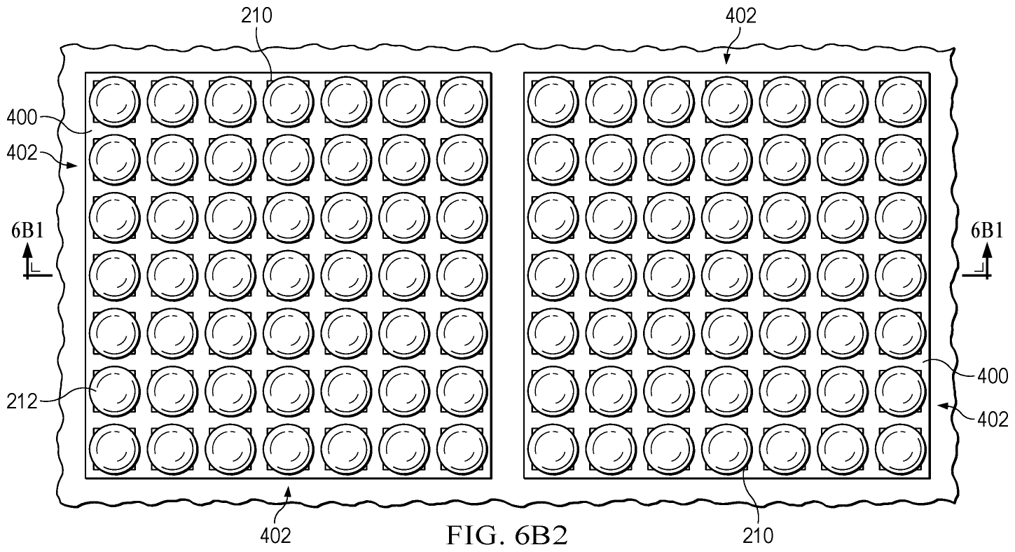

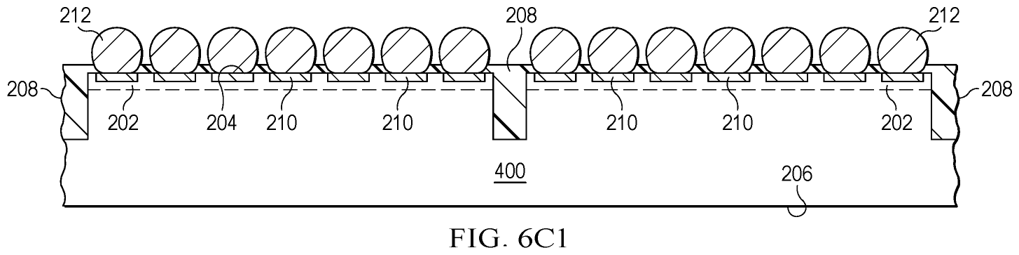

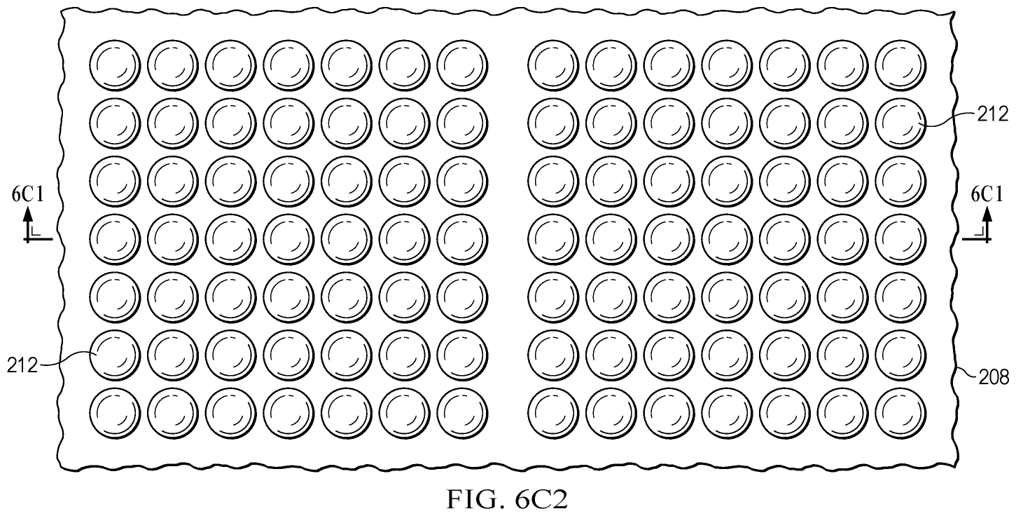

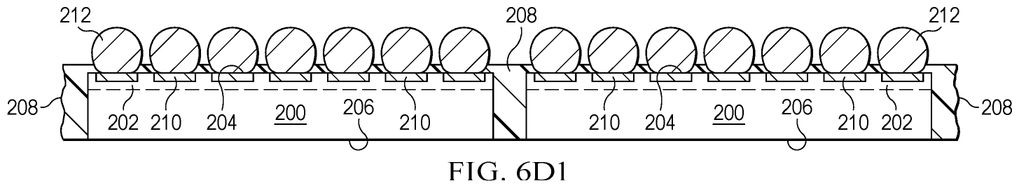

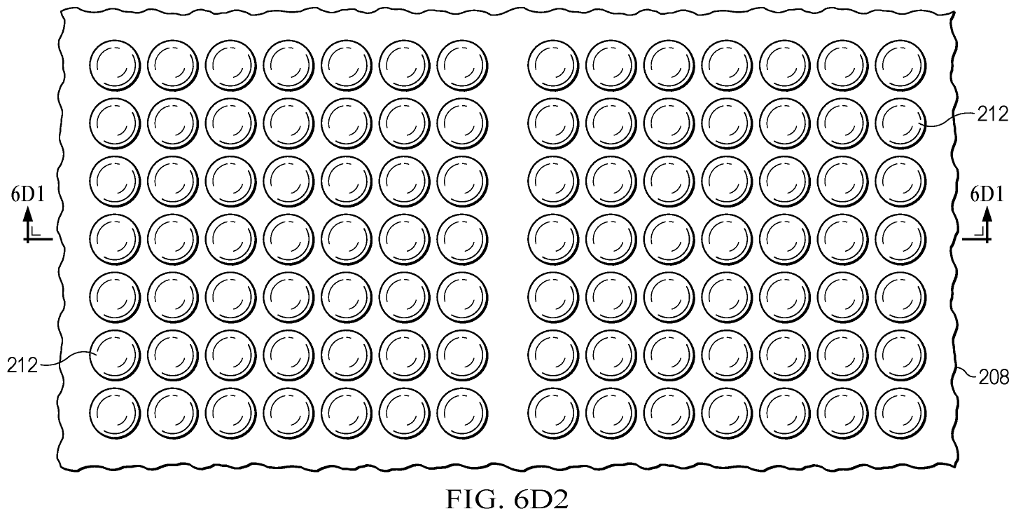

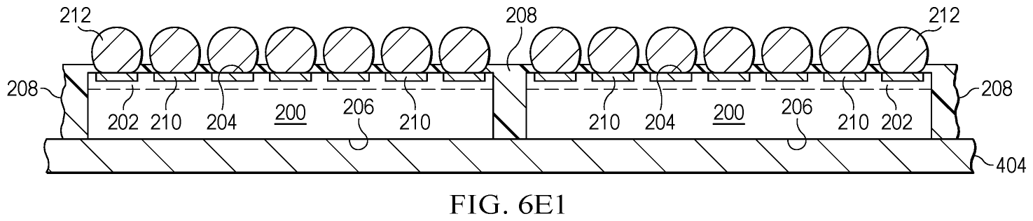

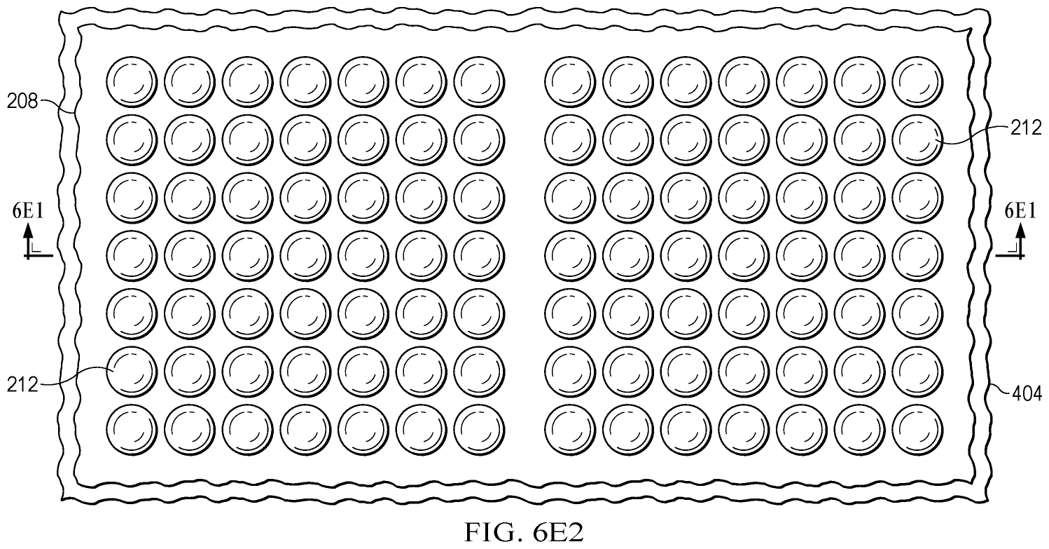

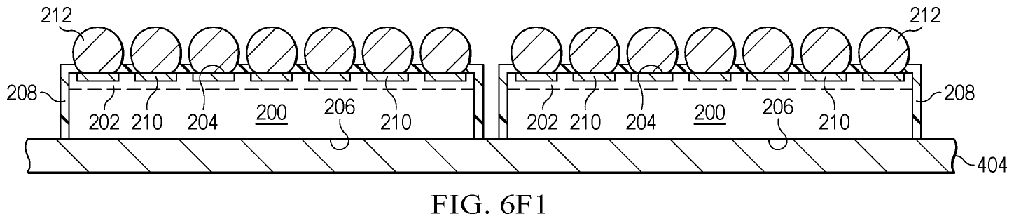

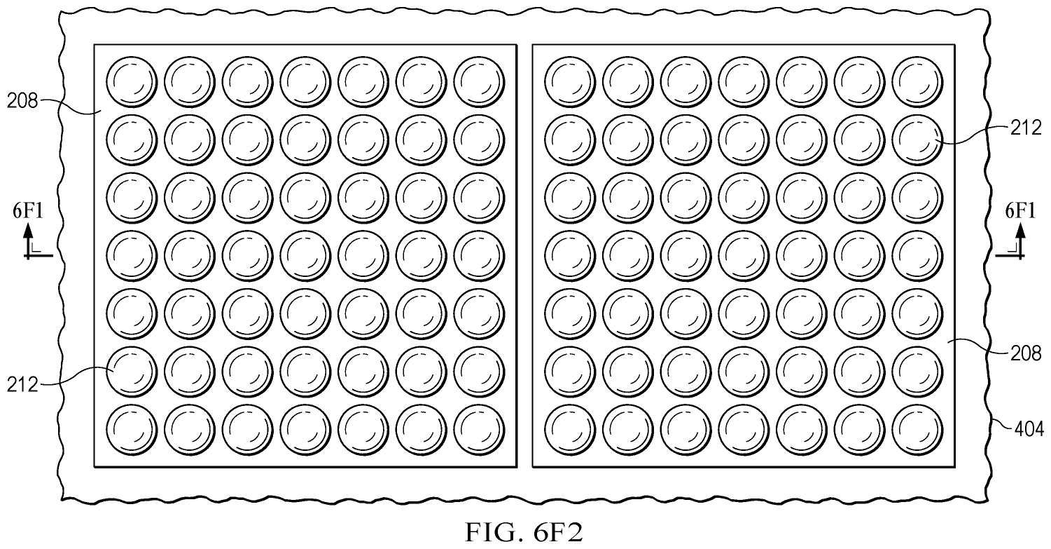

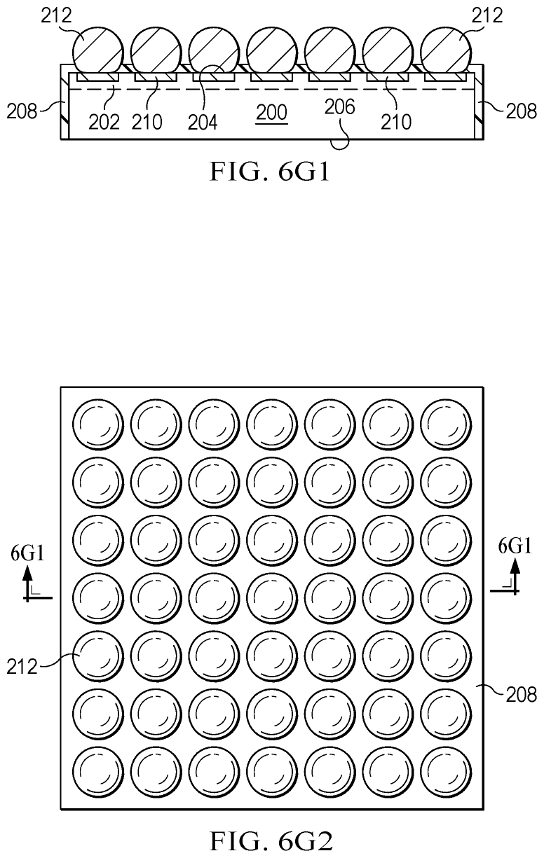

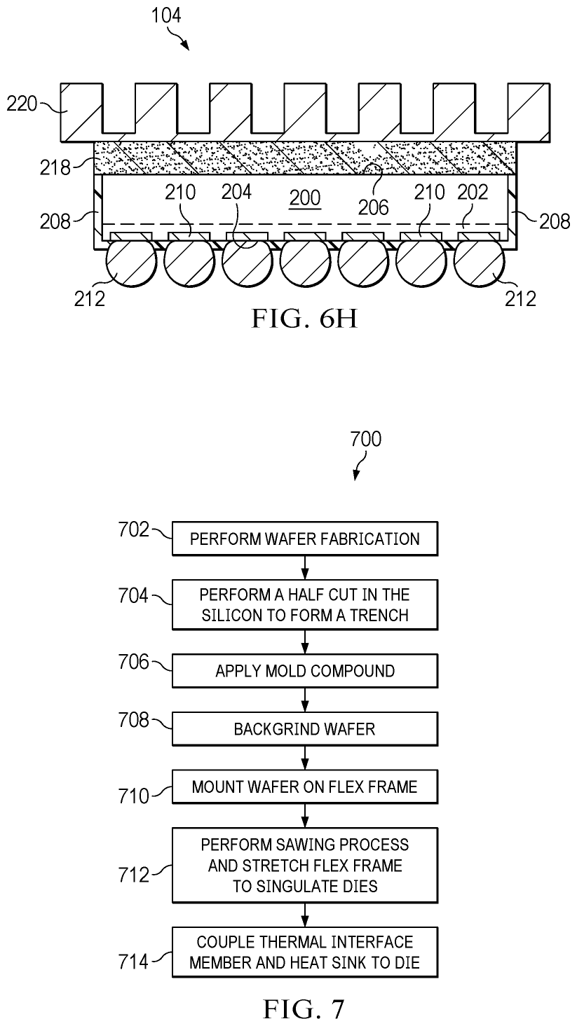

In some examples of the package 104, such as in the package 104 of FIG. 3A, the thermal pad 216 is omitted. In lieu of including the thermal pad 216, the TIM 218 is coupled directly to the non-device side 206 and to portions of the mold compound 208. For example, the TIM 218 is coupled to and contacts the same portions of the non-device side 206 and the mold compound 208 as the thermal pad 216 in the examples that include the thermal pad 216. FIGS. 6A1-6H are a process flow for manufacturing an EWCSP including a thermal interface material (TIM) and a heat sink, in accordance with various examples. For example, the process flow of FIGS. 6A1-6H depicts the manufacture of the example package 104 of FIG. 3A. FIG. 7 is a flow diagram of a method 700 for manufacturing the package 104 of FIG. 3A, in accordance with various examples. Accordingly, FIGS. 6A1-6H and FIG. 7 are now described in parallel.

The method 700 begins with performing semiconductor wafer fabrication (702). In addition to fabricating circuitry and RDL 202 in a wafer 400, additional components, such as solder bumps 212, may be coupled to the device side 204 (e.g., to contact pads 210) of the wafer 400. FIG. 6A1 shows a cross-sectional view of the solder bumps 212 being coupled to the device side 204 of the wafer 400. FIG. 6A2 is a top-down view of the structure of FIG. 6A1, in accordance with various examples.

The method 700 includes performing half-cuts in the wafer 400 to form trenches (704). A “half-cut” is a cut in the wafer 400, formed by any suitable tool such as a mechanical saw or laser, that extends from the device side 204 to approximately halfway through the thickness of the wafer 400. The half-cut does not necessarily extend precisely to the midpoint of the thickness of the wafer 400. FIG. 6B1 shows a cross-sectional view of the structure of FIG. 6A1 having trenches 402 formed therein, and more specifically, in the device side 204. The trenches 402 may be formed in the scribe streets of the wafer 400, where the wafer 400 may later be singulated. FIG. 6B2 is a top-down view of the structure of FIG. 6B1, in accordance with various examples.

The method 700 includes applying a mold compound to the wafer (706). FIG. 6C1 shows the mold compound 208 applied to the wafer 400, and more specifically, to the device side 204 of the wafer 400. The mold compound 208 also fills the trenches 402, as shown. The mold compound 208 further surrounds and contacts the solder bumps 212, as shown, such that the solder bumps 212 extend from the contact pads 210, through the mold compound 208, and to an exterior of the mold compound 208. FIG. 6C2 is a top-down view of the structure of FIG. 6C1, in accordance with various examples.

The method 700 includes backgrinding the wafer (708). FIG. 6D1 shows the wafer 400 being backgrinded such that the portions of the wafer 400 through which the trenches 402 did not extend are removed from the wafer 400. Stated another way, the wafer 400 is backgrinded until individual dies 200 are formed, as shown. FIG. 6D2 is a top-down view of the structure of FIG. 6D1, in accordance with various examples.

The method 700 includes mounting the structure of FIG. 6D1 on a flex frame (710). FIG. 6E1 shows a flex frame 404 coupled to the dies 200 and the portions of the mold compound 208 in the trenches 402. FIG. 6E2 is a top-down view of the structure of FIG. 6E1, in accordance with various examples.

The method 700 includes performing a sawing process and stretching the flex frame to singulate the dies (712). FIG. 6F1 shows a sawing process having been performed in the trenches 402, which includes sawing in the mold compound 208. FIG. 6F2 is a top-down view of the structure of FIG. 6F1, in accordance with various examples. FIG. 6G1 shows the resulting structure post-singulation and post-removal of the flex frame 404. FIG. 6G2 is a top-down view of the structure of FIG. 6G1, in accordance with various examples.

The method 700 includes coupling a thermal interface member and a heat sink to the die (714). FIG. 6H shows the TIM 218 coupled to the non-device side 206 of the die 200 and portions of the mold compound 208, and the heat sink 220 coupled to the TIM 218, as described above and in accordance with various examples. In both the packages 104 of FIGS. 2A and 3A, the mold compound 208 does not cover the non-device side 206, thus permitting heat to flow upward toward the heat sink 220 and out of the package 104. As described, in the package 104 of FIG. 3A, the thermal pad 216 is omitted. In some examples, the TIM 218 and the heat sink 220 may be omitted, and only the thermal pad 216 covers the non-device side 206, as shown in FIGS. 4H1 and 4H2. The various packages 104 described herein may be coupled to contact pads on a PCB using the solder bumps 212.

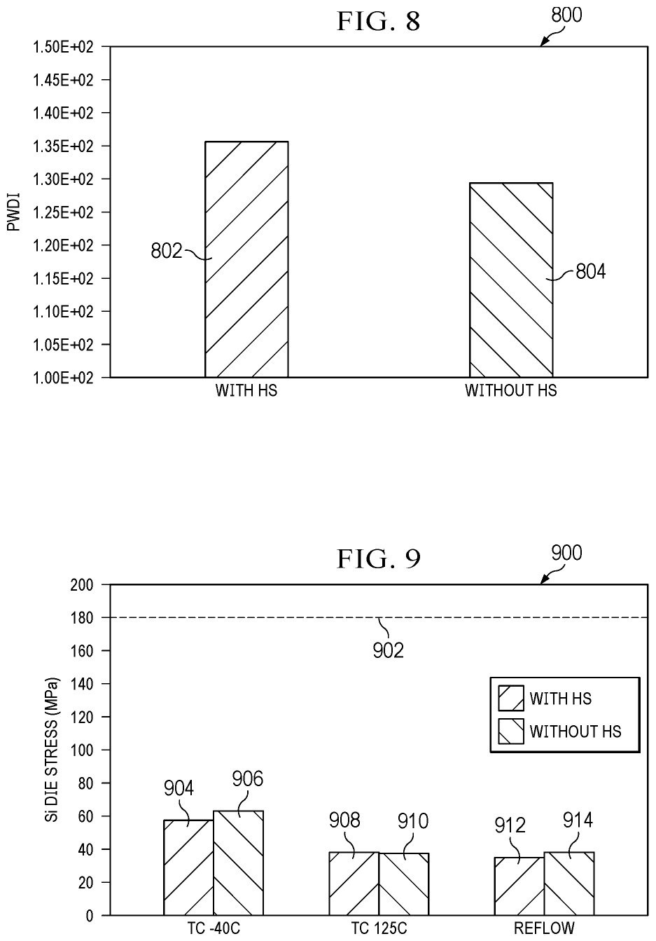

FIG. 8 is a graph 800 depicting the relative mechanical stability provided by an EWCSP including a thermal pad, a thermal interface material (TIM) and a heat sink, in accordance with various examples. More specifically, graph 800 depicts the relative risk of cracking in or near the solder bumps 212 when the package 104 includes a heat sink 220 as opposed to when the package 104 omits the heat sink 220. The graph 800 depicts the plastic work density increment (PWDI) under thermal capacitance (TC) loading of the packages 104 to evaluate ball grid array (BGA) damage, such as at or near the solder bumps 212. PWDI is a measure of the plastic work, or plastic deformation, of a structure due to the application of external forces. TC loading refers to the thermal mass or capacitance that a device or a specific region of an integrated circuit has. TC loading is a measure of how much heat energy the device or region can store for a given temperature change. The thermal capacitance of a structure is determined by its physical properties, dimensions, and materials. The graph 800 depicts bar 802, which indicates the PWDI of a package 104 with the heat sink 220, and bar 804, which indicates the PWDI of a package 104 without the heat sink 220. As shown by bars 802 and 804, there is a less than 5% difference between the PWDIs, meaning that the heat sink 220 can be included in the package 104 without a meaningful impact on the mechanical stability of the package 104 (as measured by PWDI).

FIG. 9 is a graph 900 depicting the relative die stresses experienced under different ambient conditions by an EWCSP including a thermal pad, a thermal interface material (TIM) and a heat sink, in accordance with various examples. Such die stresses can lead to die cracks, thereby compromising the functionality integrity of the die. The graph 900 includes a y-axis depicting die stress in mega pascals (MPa), a threshold 902 that indicates the fracture strength criteria for the die (i.e., the maximum permissible die stress), bars 904, 908, and 912 that indicate die stresses experienced in packages 104 with the heat sink 220 included, and bars 906, 910, and 914 that indicate die stresses experienced in packages 104 with the heat sink 220 excluded. As shown, the bar 904 indicates an approximately 10% reduction in die stress at −40 degrees Celsius under TC loading relative to bar 906. Similarly, the bar 912 indicates an approximately 10% reduction in die stress at reflow temperatures relative to bar 914. The die stresses experienced at 125 degrees Celsius under TC loading are approximately the same across the bars 908 and 910, as shown. Thus, the graph 900 indicates that the likelihood of a die crack is generally decreased when the heat sink 220 is included in the package 104.

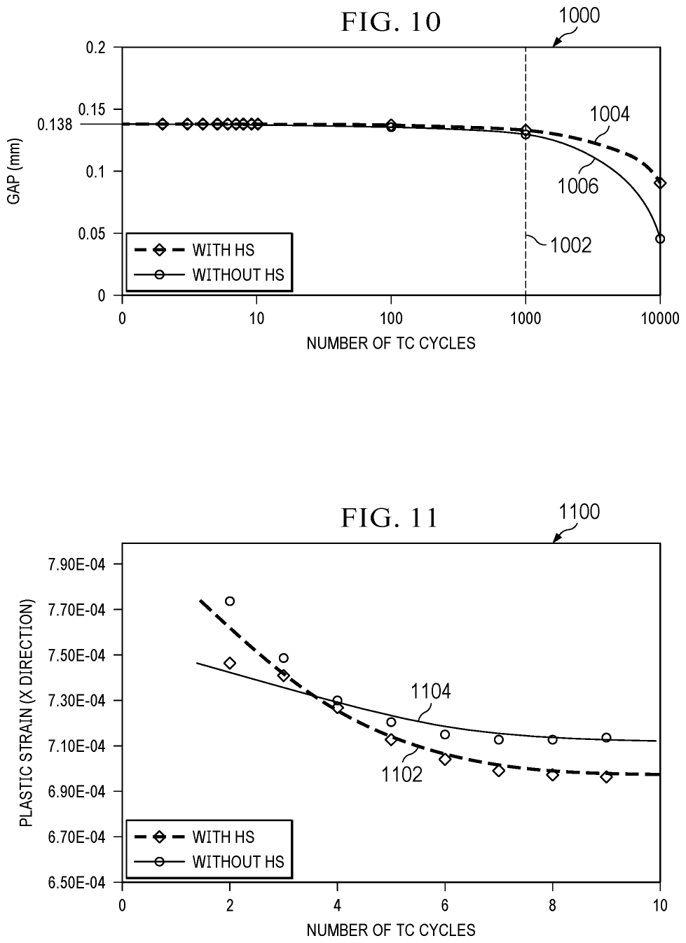

FIG. 10 is a graph 1000 depicting the relative solder bump bridging risk of an EWCSP including a thermal pad, a thermal interface material (TIM) and a heat sink, in accordance with various examples. More specifically, the graph 1000 depicts the likelihood of the gap between solder bumps 212 decreasing to the point of contacting each other and forming a short circuit. The graph 1000 indicates the number of TC cycles in log scale on the x-axis, and the graph 1000 indicates the gap in millimeters between immediately adjacent solder bumps 212. Curve 1004 indicates the performance of a package 104 with the heat sink 220, and curve 1006 indicates the performance of a package 104 without the heat sink 220. As shown, performance is nearly identical until 1000 TC cycles have elapsed. The 1000 TC mark is a threshold 1002 after which the relative performances of the curves 1004 and 1006 differ. Specifically, the gap between adjacent solder bumps 212 decreases more for curve 1006 than for curve 1004. Thus, the inclusion of the heat sink 220 decreases the likelihood of shorting between adjacent solder bumps 212.

FIG. 11 is a graph 1100 depicting the relative solder bump bridging risk of an EWCSP including a thermal pad, a thermal interface material (TIM) and a heat sink, in accordance with various examples. Specifically, graph 1100 depicts the relative risk of bridging between immediately adjacent solder bumps 212 in terms of plastic strain in the horizontal direction (i.e., the x direction). In graph 1100, the x-axis depicts the number of TC cycles, and the y-axis depicts plastic strain. The graph 1100 includes curves 1102 and 1104. Curve 1102 indicates the performance of the package 104 with the heat sink 220, and curve 1104 indicates the performance of the package 104 without the heat sink 220. As shown, as the number of TC cycles increases, the plastic strain experienced by the package 104 including the heat sink 220 becomes less than that experienced by the package 104 excluding the heat sink 220. The package 104 including the heat sink 220 has superior performance relative to the package 104 excluding the heat sink 220 after the ˜3.5 TC cycle mark.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A wafer chip scale package (WCSP), comprising:
a semiconductor die having a device side in which circuitry is formed and a non-device side opposite the device side;
a solder bump electrically coupled to the circuitry;
a mold compound in contact with the device side, the solder bump, and four lateral sides of the semiconductor die; and
a thermal pad in contact with the non-device side of the semiconductor die and the mold compound.

2. The WCSP of claim 1, wherein the mold compound is not in contact with the non-device side of the semiconductor die.

3. The WCSP of claim 1, wherein the WCSP has a junction-to-ambient thermal resistance value ranging up to 50 degrees Celsius per watt.

4. The WCSP of claim 1, wherein the thermal pad comprises gold or tin.

5. The WCSP of claim 4, wherein the thermal pad has a thickness ranging up to 4 microns.

6. The WCSP of claim 1, further comprising a thermal interface material in contact with the thermal pad, the thermal interface material comprising a phase change compound and a thermally conductive polyimide film.

7. The WCSP of claim 6, further comprising a heat sink in contact with the thermal interface material and comprising a fin structure.

8. The WCSP of claim 6, wherein the thermal interface material has a thickness ranging from 0.09 millimeters to 1.1 millimeters.

9. The WCSP of claim 6, wherein the thermal interface material has a thermal conductivity coefficient of at least 1.5 watts per meter-Kelvin.

10. A wafer chip scale package (WCSP), comprising:
a semiconductor die having a device side in which circuitry is formed and a non-device side opposite the device side;
a solder bump coupled to the device side;
a mold compound contacting the device side and the solder bump;
a thermal interface material coupled to and supported by the semiconductor die, the thermal interface material having a thickness between 0.1 millimeters and 0.5 millimeters and a thermal conductivity coefficient of at least 1.5 watts per meter-Kelvin (W/mK); and
a heat sink coupled to the thermal interface material.

11. The WCSP of claim 10, wherein the mold compound contacts four lateral sides of the semiconductor die and does not contact the non-device side of the semiconductor die.

12. The WCSP of claim 10, wherein the thermal interface material comprises a gap filler pad.

13. The WCSP of claim 12, wherein the gap filler pad comprises a silicone compound.

14. The WCSP of claim 10, wherein the thermal interface material comprises a phase change compound and a polyimide film.

15. The WCSP of claim 10, wherein the thermal interface material comprises an acrylic adhesive.

16. A method for manufacturing a semiconductor device, comprising:
positioning solder bumps on a device side of a semiconductor wafer, the device side having circuitry formed therein;
cutting through a thickness of the semiconductor wafer to produce partial first and second trenches;
applying a mold compound to the device side, the solder bumps, and the partial first and second trenches;
backgrinding the semiconductor wafer to reduce a thickness of the semiconductor wafer, the backgrinding producing first and second semiconductor dies;
coupling a thermal pad to a first non-device side of the first semiconductor die and a second non-device side of the second semiconductor die;
separating the first and second semiconductor dies to produce a wafer chip scale package (WCSP);
coupling a thermal interface material to the thermal pad of the WCSP; and
coupling a heat sink to the thermal interface material.

17. The method of claim 16, wherein the thermal interface material has a thermal conductivity coefficient of at least 1.5 watts per meter-Kelvin.

18. The method of claim 16, wherein the thermal interface material has a thickness ranging from 0.09 mm to 1.1 mm.

19. The method of claim 16, wherein the thermal interface material comprises a phase change compound.

20. The method of claim 16, wherein the thermal interface material comprises a thermally conductive polyimide film.
